(19) United States
(12) Patent Application Publication
(10) Pub. No.: US 2016/0198562 A1
(43) Pub. Date: Jul. 7, 2016

(54) Bus Structure with sealed dielectric interface to semiconductor switch package input connections for reduced terminal spacing and lower inductance while meeting regulatory requirements

(71) Applicants: Michael BRUBAKER, Loveland, CO (US); Terry HOSKING, Barre, VT (US); SBE INC., Barre, VT (US)

(72) Inventors: Michael Brubaker, Loveland, CO (US); Terry Hosking, Barre, VT (US)

(21) Appl. No.: 14/916,606

(22) PCT Filed: Sep. 19, 2014
(86) PCT No.: PCT/US14/56468

§ 371 Date: Mar. 4, 2016

(30) Foreign Application Priority Data
Sep. 24, 2013 (US) 61881724

(51) Int. Cl. H05K 1/02; H01B 17/56; H01B 17/00

(52) U.S. Cl. CPC H05K 1/0256; H01B 17/005; H01B 17/56; H05K 2201/0746; H05K 2201/0761; H05K 2201/10053

(57) ABSTRACT

Semiconductor switch modules have positive and negative electrical input connections which must be spaced adequately to prevent a short circuit flashover between the polarities. This terminal spacing is defined by the strike distance through air or creepage distance through air along an insulating surface between the two input connections given the operating voltage per regulatory agency requirements. The inductance of the switch connections is ultimately limited by this terminal spacing. A novel conformal solid insulation scheme between the bus structure and switch module eliminates the strike or creepage paths through air and allows for reduced terminal spacing and lower inductance while meeting regulatory agency requirements.

### TECHNICAL FIELD

The technical field of the invention is power conversion systems using solid state switching. For example, inverters which convert DC power to AC power for applications such as electric vehicles and solar power. Such systems require an optimized interface between the DC bus and the solid state switch module (or modules) to achieve the best possible performance.

### BACKGROUND ART

Semiconductor switch modules are comprised of an insulating case with external metal positive and negative input terminals which must be separated by sufficient spacing to comply with regulatory agency requirements for strike distance (through air) and creepage distance (over a solid insulating surface in air) based on the operating voltage. Typical commercially available modules are half-bridges or full-bridges with the positive and negative input terminals deployed in side-by-side or in-line configurations. In both cases, the input geometry is dictated by the terminal spacing with air as the dielectric, which has a significant contribution to the equivalent series inductance (ESL) seen by the semiconductor switches. Alternative topologies including strip line input configurations have also been demonstrated, but the terminal spacing and ESL is still dictated by the same requirements as described above.

Minimizing the ESL is critical to manage voltage overshoot which occurs at switch turn-off and can lead to catastrophic device failure. Overshoot is defined by the relationship V=L×dl/dt where V is the voltage in Volts, L is the inductance in Henries, and dl/dt is the rate of current change in Amperes per second. For a given dl/dt value, reducing the value of L results in a lower value of V. Reducing the overshoot voltage allows safely operating at higher DC voltages, which improves the power handling capability of the switch module. While prior art does address teachings of how to make lower inductance bus structures (U.S. Pat. Nos. 8,193,449 and 7,798,833), the issue of reducing dielectric clearances to improve ESL has not been addressed. The uniqueness of the present invention is in the use of a bus structure to facilitate placement of solid insulation between the terminals of a switch module (which is otherwise designed with tab-style connections) to eliminate the air strike distance created by the tab geometry and allow for reduced spacing and lower inductance without violating regulatory agency requirements for creepage and strike distance.

### SUMMARY OF THE INVENTION

### Technical Problem

Voltage overshoot occurring at switch turn-off limits the safe DC operating voltage of solid state switch modules used for power conversion applications. The voltage overshoot is defined as V=L×dl/dt where V is the voltage in Volts, L is the inductance in Henries, and dl/dt is the rate of current change in Amperes per second. For a given dl/dt condition, the overshoot voltage can be reduced by making the value of the inductance L smaller. According to Maxwell's equations, the inductance is defined by the loop area of the connection between the semiconducting switch input terminals. As such a larger terminal spacing results in a larger inductance. For conventional switch modules, the terminal spacing is defined by the strike (through air) and creepage (through air over an insulating surface) distances between the positive and negative input terminals to meet regulatory requirements for a given operating voltage. The problem is thus that the inductance of the semiconductor switch connection is limited by the dielectric strength of air. Further discussion of inductance for switch module inputs is provided elsewhere [1-3].

### Solution to Problem

The present invention uses a novel bus and insulation scheme to eliminate the air-insulated strike and creepage paths between traditional tabbed switch module input terminals. A terminal geometry is created using parallel conducting plates (one positive polarity and one negative polarity) separated by a layer of solid insulation sufficient to hold off the required operating voltage. Additional insulation layers can be added on the outside faces of the conducting plates to facilitate edge sealing. Through-hole connections are made between each polarity plate and the corresponding polarity input terminals on the switch module. Note that the “throat” regions where a connection of one polarity passes through a plate of the opposite polarity utilize edge sealing insulation to minimize the spacing while providing the required insulation level. Note further that conducting bushings are often utilized to facilitate compression of metal to metal contacts between the bus plates and switch module terminals.

A novel conformal insulating layer is applied to the bus plate which contacts the switch module. This insulation is secured by the compression of the input terminal mounting screws or by adhesive bonding and serves to eliminate any strike or creepage paths through air between the positive and negative terminals. As such, the tabbed switch module terminal spacing is now defined by the properties of the solid insulating layer and can be dramatically reduced without violating any air strike or creepage limits. While the idea of using solid insulation to reduce spacing between conductors at different potentials is well known, the present invention is unique in that the bus structure serves as the substrate for the solid insulation. As such, the solid insulation does not achieve the desired function unless it is integrated with the bus structure for interfacing with the switch module. This technique can be applied to an existing commercially available single or multi-phase switch module utilizing tabbed connections or utilized to allow fabrication of new modules with reduced terminal spacing. In either case, significantly reduced ESL is achieved such that operating voltages can be increased without the traditional limit of voltage overshoot.

### Advantageous Effects of Invention

Elimination air as the limiting dielectric between the switch module terminals allows for reduction of the terminal spacing. This in turn reduces the inductance and allows for safe operation at higher DC voltages without fear of voltage overshoot causing switch failure at switch turn off. As such, the power density of the converter is improved by allowing safe operation at higher voltage. This has significant impact on cost, weight, and size for power conversion systems.

### BRIEF DESCRIPTION OF THE DRAWINGS

FIG. 1 illustrates the creepage and strike paths between the positive and negative input terminals for a state-of-the-art “side-by-side” tabbed connection half-bridge module. Note that this represents a single phase module, but multi-phase constructions are possible as well. Not to scale.

FIG. 2 illustrates the creepage and strike paths between the positive and negative input terminals for a state-of-the-art “in-line” tabbed connection half-bridge module. Note that some models have multiple pairs of positive and negative inputs for current sharing. Note further that multi-phase constructions are possible as well. Not to scale.

FIG. 3 illustrates the conventional tab connection method that is used for connecting to a state-of-the-art “side-by-side” or “in-line” half-bridge module. The strike and creepage paths through air define the tab spacing and thus the inductance of the connection. The geometry shown also applies to multi-phase switch module constructions.

FIG. 4 shows the preferred embodiment of present invention where a conformal insulation layer is applied to the laminar bus and compressed between the bus structure and the switch module to eliminate failure paths through air (or over a surface in air) such that spacing can be reduced. Not scale. Note that the preferred embodiment can be applied to any switch module configuration having any number of input terminals.

### DESCRIPTION OF EMBODIMENTS

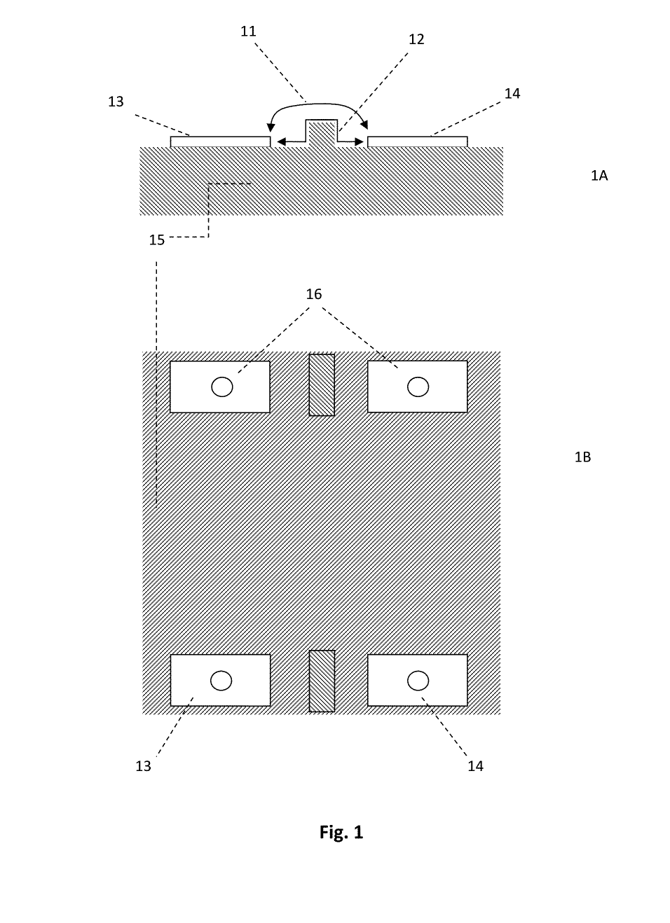

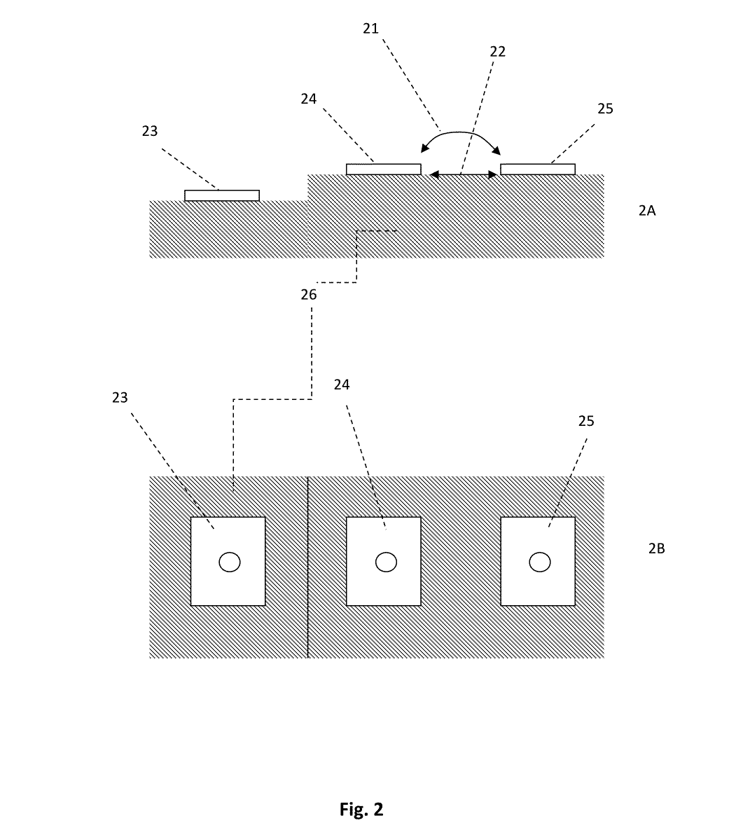

In order to clearly define the present invention, factors that dominate the terminal spacing of semiconductor switch modules must be understood. A “side-by-side” input configuration of a half-bridge switch is shown in FIG. 1 with respective side view (1A) and top view (1B). The strike path (11) and creepage path (12) are illustrated through air between the positive terminal (13) and the negative terminal (14). The creepage path (12) is through air across the insulating switch body (15). The output terminals (16) have a similar spacing requirement but the inductance of the output connections is not important. An “in-line” input configuration of a half-bridge switch is shown in FIG. 2 with respective side view (2A) and top view (2B). The strike path (21) and creepage path (22) are illustrated through air between the positive terminal (24) and negative terminal (25). The creepage path (22) is across the insulating switch body (26). The output terminal (23) does not affect the inductance of the input connections.

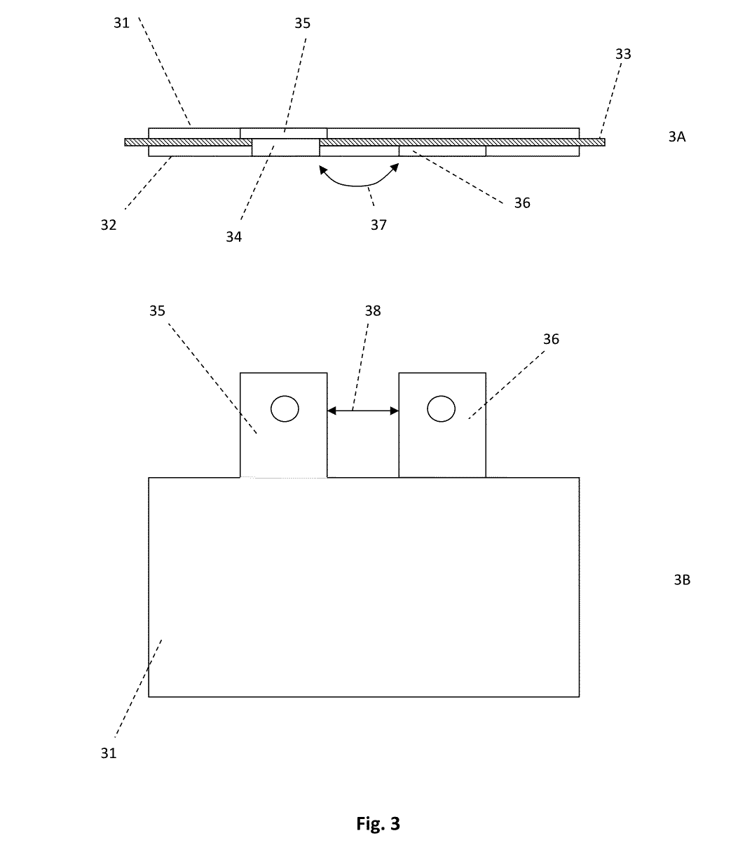

The strike and creepage paths ([11] and [12] from FIG. 1 and [21] and [22] from FIG. 2) are limited by the dielectric strength of air. A typical tab input configuration with a laminar bus structure is illustrated in FIG. 3 with respective side view (3A) and top view (3B). The positive bus conductor (31) is separated from the negative bus conductor (32) by a suitable insulator (33). The positive bus conductor (31) connects to the appropriate positive terminal (13 from FIG. 1 or 24 from FIG. 2) on the switch module and the negative bus conductor (32) connects to the appropriate negative terminal (14 from FIG. 1 or 25 from FIG. 2) on the switch module. Note that a bushing (34) is added under the positive bus conductor (31) tab (35) such that the mating surface is in the same plane as the negative bus conductor (32) tab (36). The creepage distance (37) between the positive and negative bus tabs (35 and 36) is defined as a path along the insulating surface of the switch module body (15 from FIG. 1 or 26 from FIG. 2). The strike distance (38) between the positive and negative bus tabs (35 and 36) is the shortest path through air with no insulating surface.

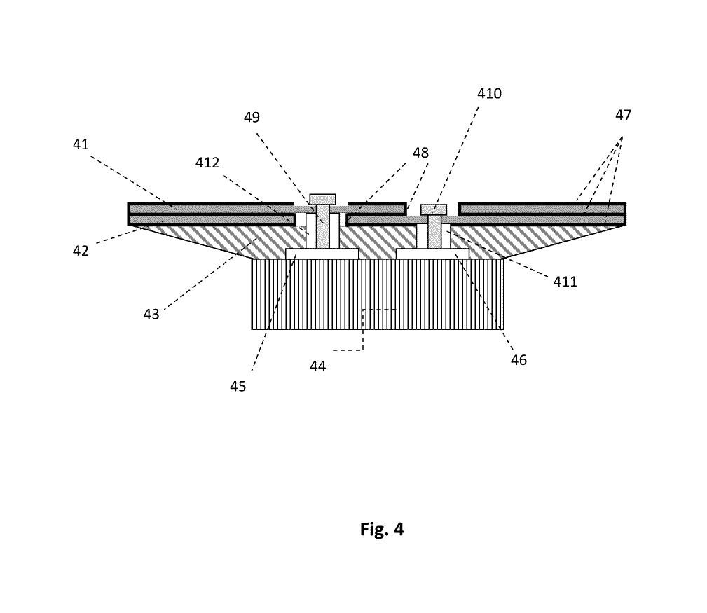

The present invention eliminates air as the dielectric limit between the positive and negative terminals with one embodiment as illustrated in FIG. 4. A bus structure comprised on a positive bus plate (41) and negative bus plate (42) is used to compress conformal insulation (43) against the insulating switch module body (44), positive input terminal (45) and negative input terminal (46). The positive bus plate (41) and negative bus plate (42) are insulated from one another with an insulating sheet (47). Note that the insulating sheet (47) is applied to all sides of the positive bus plate (41) and negative bus plate (42). This allows for a sealed edge (48) to be established at the transition points where the positive connecting bolt (49) and negative connecting bolt (410) connect respectively to the positive input terminal (45) and negative input terminal (46) of the switch module. In each case, a conducting bushing (411 and 412) is compressed between the respective bus plate and switch module terminal. The creepage and strike distances between the positive terminal (45) and the negative terminal (46) are now defined by the properties of the conformal insulation layer (43) rather than air such that the spacing can be reduced to reduce the ESL while still meeting regulatory requirements.

### INDUSTRIAL APPLICABILITY

The industry typically provides high-power semiconductor switch modules in three packages—small flexible modules with pin connections, high power modules with low inductance through holes or tabs, and multi-switch modules with tab style input connections. The present invention provides for a way to connect to a half-bridge or multi-switch module while mitigating the typically high inductances created by tab to tab connections. The invention provides this benefit without violating regulatory agency guidelines for creepage and strike distances between terminals (such as UL).

### REFERENCE TO DEPOSITED BIOLOGICAL MATERIAL

Not Applicable

### SEQUENCE LISTING FREE TEXT

Not Applicable

### CITATION LIST

### Patent Literature

U.S. Pat. No. 8,193,449 (Esmaili et al)

U.S. Pat. No. 7,798,833 (Holbrook)

### Non-Patent Literature

[1] E. D. Sawyer, “Low Inductance—Low Temp Rise DC Bus Capacitor Properties Enabling the Optimization of High Power Inverters”, Proceedings of PCIM, Nuremberg, Germany, May 2010, http://www.sbelectronics.com/technology/technical-papers/

[2] M. A. Brubaker, T. A. Hosking, and E. D. Sawyer, “Characterization of Equivalent Series Inductance for DC Link Capacitors and Bus Structures”, Proceedings of PCIM, Nuremberg, Germany, May 2012, http://www.sbelectonics.com/technology/technical-papers/

[3] M. A. Brubaker, H. C. Kirbie, and T. A. Hosking, “Integrated DC Link Capacitor/Bus Structures to Minimize External ESL Contribution to Voltage Overshoot”, Proceedings of the 1st Annual IEEE Transportation Electrification Conference, June 18-22, Dearborn Mich., 2012, http://www.sbelectronics.com/technology/technical-papers/

### SEQUENCE LISTING

Not applicable

What is claimed is:

1: A compliant insulation layer applied to a laminated bus structure and interfaced via the bus connections with a semiconductor switch module including but not limited to one or more half-bridges, transistors, silicon controlled rectifiers, or diodes to eliminate failure paths through air or across a surface in air between the input terminals so as to allow reduced terminal spacing to decrease package size and minimize equivalent series inductance while meeting or exceeding third party regulatory agency requirements for electrical clearance when installed.

2: The device in claim 1 where the insulation layer is comprised of one or more flexible 0-Rings.

3: The device in claim 1 where a protruding feature is applied to the switch module package to compress the compliant insulation.

4: The device in claim 1 where the compliant insulation is a separate sheet of suitable insulating material.

5: The device in claim 1 where the compliant insulation is a flexible adhesive.

6: The device in claim 1 where an existing module is modified to accommodate the flexible insulation layer.

7: The device in claim 1 where a custom module is designed to take advantage of the reduced terminal space.
